(19) United States
(12) Patent Application Publication
(10) Pub. No.: US 2026/0150323 A1
(43) Pub. Date: May 28, 2026

(54) SEMICONDUCTOR DEVICE, METHOD OF MANUFACTURING THE SAME

(71) Applicant: HUNAN SAN'AN SEMICONDUCTOR CO., LTD., Changsha (CN)

(72) Inventors: Shuai CHEN, Changsha (CN); Yutao FANG, Changsha (CN); Deyang XIA, Changsha (CN); Jie ZHANG, Changsha (CN)

(21) Appl. No.: 19/177,682

(22) Filed: Apr. 14, 2025

Related U.S. Application Data
(63) Continuation of application No. PCT/CN2023/107211, filed on Jul. 13, 2023.

(30) Foreign Application Priority Data
Oct. 14, 2022 (CN) 202211263287.8

(51) Int. Cl. H10D 30/47; H10D 30/01

(52) U.S. Cl. CPC H10D 30/475; H10D 30/015

(57) ABSTRACT

A semiconductor device includes: a substrate, a buffer layer, a channel layer and a barrier sequentially stacked; a cap layer, disposed on the barrier layer; a gate, disposed on the cap layer; a source, disposed on the barrier layer; and a drain, disposed on the barrier layer, where the drain and the source are disposed on two sides of the gate. The semiconductor device includes multiple P-type stacked layers disposed between the barrier layer and the cap layer along a direction from the substrate to the buffer layer. Each P-type stacked layer includes a first P-type doped GaN layer disposed proximate to the barrier layer and a first P-type doped layer disposed on the first P-type doped GaN layer. A doping concentration of the first P-type doped GaN layer is configured to decrease from a side proximate to the first P-type doped layer to a side proximate to the substrate.

### CROSS-REFERENCE TO RELATED APPLICATIONS

This application is a continuation of International Patent Application No. PCT/CN2023/107211, filed on Jul. 13, 2023, which claims the priority of Chinese Patent Application No. 202211263287.8, filed on Oct. 14, 2022, both of which are herein incorporated by reference in their entirety.

### TECHNICAL FIELD

The disclosure relates to the technical field of semiconductors, and more particularly to a semiconductor device and a method of manufacturing the same.

### BACKGROUND

Heterostructure based on high electron mobility transistor (HEMT) has spontaneous polarization and piezoelectric polarization effects, so that high-density two-dimensional electron gas (2DEG) can be generated without other technologies such as doping. The heterostructure based on HEMT has high mobility, and is suitable for high-power and high-frequency electronic devices. Existing HEMT power devices include depletion mode and enhancement mode. Specifically, the 2DEG induced by the polarization of the aluminum gallium nitride/gallium nitride (AlGaN/GaN) interface epitaxially grown in group III nitrides makes the prepared HEMT often depletion mode (D-mode), but the enhancement mode (E-mode) has lower loss, simpler circuit and higher safety.

At present, a P-type gallium nitride (P-GaN) cap layer technology is widely used in the method for preparing the enhancement mode HEMT. By epitaxially growing P-GaN, an energy band of the 2DEG channel is raised, and the 2DEG in a gate channel is depleted to form the enhancement mode. However, the P-GaN cap layer technology of the enhancement mode HEMT often has the problem of decreased mobility in a non-gate region.

### SUMMARY

In order to at least solve one or more of the technical problems mentioned above, the disclosure proposes a semiconductor device and a manufacturing method thereof in multiple aspects to effectively prevent a mobility in a non-gate region from decreasing.

In the first aspect, the disclosure provides a semiconductor device, including a substrate, a buffer layer, a channel layer, a barrier layer, a cap layer, a gate, a source, and a drain. The buffer layer is disposed on the substrate. The channel layer is disposed on the buffer layer. The barrier layer is disposed on the channel layer. The cap layer is disposed on the barrier layer. The gate is disposed on the cap layer. The source is disposed on the barrier layer. The drain is disposed on the barrier layer, and the drain and the source are disposed on two sides of the gate respectively. The semiconductor device further includes multiple P-type stacked layers, and the multiple P-type stacked layers are disposed between the barrier layer and the cap layer along a direction from the substrate to the buffer layer. Each of the multiple P-type stacked layers includes a first P-type doped gallium nitride (GaN) layer disposed proximate to the barrier layer and a first P-type doped layer disposed on the first P-type doped GaN layer. A doping concentration of the first P-type doped GaN layer is configured to decrease from a side proximate to the first P-type doped layer to a side proximate to the substrate.

In the second aspect, the disclosure provides a manufacturing method of a semiconductor device, including:
providing a semiconductor epitaxial structure;
disposing multiple prefabricated P-type stacked layers on the semiconductor epitaxial structure along a direction from the substrate to the buffer layer;
forming an original cap layer on the multiple prefabricated P-type stacked layers;
etching the original cap layer and the multiple prefabricated P-type stacked layers, and annealing the semiconductor device after etching the original cap layer and the multiple prefabricated P-type stacked layers, so that the prefabricated P-type stacked layers is formed into the P-type stacked layers.

The semiconductor device provided by the disclosure includes the multiple P-type stacked layers disposed between the barrier layer and the cap layer along the direction from the substrate to the buffer layer, each of the multiple P-type stacked layers includes the first P-type doped GaN layer disposed on the barrier layer and the first P-type doped layer disposed on the first P-type doped GaN layer, and the doping concentration of the first P-type doped GaN layer is configured to decrease from the side proximate to the first P-type doped layer to the side proximate to the substrate. The first P-type doped GaN layer in the P-type stacked layers can effectively block and reduce the diffusion of doping impurities in a P-type gate to the barrier layer during the manufacturing process of the semiconductor device, thereby improving the problem of decreased mobility in the non-gate region, and ultimately reducing the on-resistance of the device and improving the on-performance of the device.

### BRIEF DESCRIPTION OF DRAWINGS

FIG. 1 illustrates a schematic structural diagram of a semiconductor device according to some embodiments of the disclosure.

FIG. 2 illustrates another schematic structural diagram of the semiconductor device according to some embodiments of the disclosure.

FIG. 3 illustrates a flowchart of a manufacturing method of a semiconductor device according to some embodiments of the disclosure.

FIG. 4 illustrates another flowchart of the manufacturing method of the semiconductor device according to some embodiments of the disclosure.

FIG. 5 illustrates a flowchart of a manufacturing method of a semiconductor epitaxial structure according to some embodiments of the disclosure.

FIG. 6 illustrates a schematic structural diagram of an epitaxial structure of a semiconductor device according to some embodiments of the disclosure.

### DETAILED DESCRIPTION OF EMBODIMENTS

In current manufacturing methods for enhancement-mode HEMTs, a P-GaN cap layer technique is widely employed as it eliminates the adverse effects of ion etching on channel electrons, enabling semiconductor devices to achieve high saturation current. However, in order to ensure complete depletion of the 2DEG in the channel by the P-GaN cap layer, the heterostructure typically requires a thinner barrier layer, for example, a thickness of the barrier layer is about 25 nm. Meanwhile, ineffective doped such as insufficient doped Mg) in the P-GaN cap layer tends to generate defects, degrading its crystalline quality. These defects can readily permeate into the underlying thin barrier layer, enhancing electron scattering within the barrier and causing decreased mobility of the semiconductor device.

Aiming at the above problems, the disclosure provides a semiconductor device.

The embodiments of the disclosure are described in detail in conjunction with drawings below.

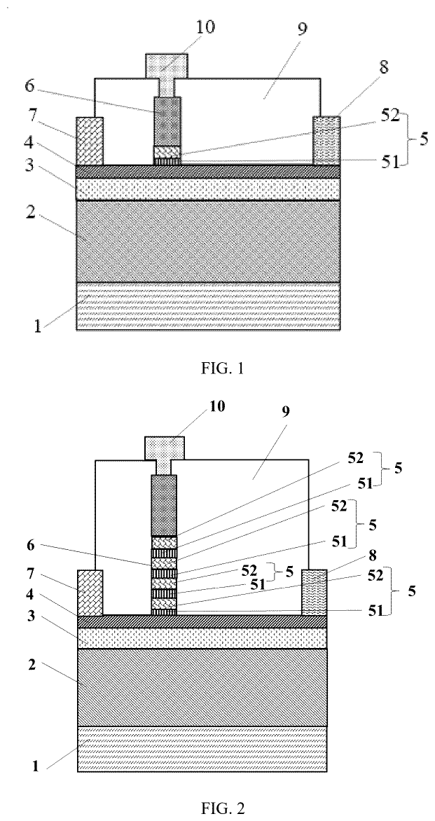

FIG. 1 illustrates a schematic structural diagram of a semiconductor device according to some embodiments of the disclosure.

Referring to FIG. 1, the semiconductor device provided by the embodiments of the disclosure may include a substrate 1, a buffer layer 2, a channel layer 3, a barrier layer 4, a cap layer 6, a gate 10, a source 7, and a drain 8. The buffer layer 2 is disposed on the substrate 1. The channel layer 3 is disposed on the buffer layer 2. The barrier layer 4 is disposed on the channel layer 3. The cap layer 6 is disposed on the barrier layer 4. The gate 10 is disposed on the cap layer 6. The source 7 is disposed on the barrier layer 4. The drain 8 is disposed on the barrier layer 4, and the drain 8 and the source 7 are disposed on two sides of the gate 10 respectively.

The semiconductor device provided by the embodiments of the disclosure further includes multiple P-type stacked layers 5, and the multiple P-type stacked layers 5 are disposed between the barrier layer 4 and the cap layer 6 along a direction from the substrate 1 to the buffer layer 2. Each P-type stacked layer 5 includes a first P-type doped GaN layer 51 disposed proximate to the barrier layer 4 and a first P-type doped layer 52 disposed on the first P-type doped GaN layer 51.

A direction of the substrate 1 pointing to the cap layer 6 is defined as upward, thus the substrate 1, the buffer layer 2, the channel layer 3, the barrier layer 4, the first P-type doped GaN layer 51, the first P-type doped layer 52 (the first P-type doped GaN layer 51 and the first P-type doped layer 52 constitute a P-type stacked layer 5), and the cap layer 6 are sequentially arranged in that order from bottom to top.

In the embodiments of the disclosure, a doping concentration of the first P-type doped GaN layer 51 in the P-type stacked layer 5 is configured to decrease from a side proximate to the first P-type doped layer 52 to a side proximate to the substrate 1. That is, the doping concentration of the first P-type doped GaN layer 51 gradually decreases from top to bottom.

The semiconductor device provided by the disclosure includes the multiple P-type stacked layers 5 disposed between the barrier layer 4 and the cap layer 6 along the direction from the substrate 1 to the buffer layer 2, each of the multiple P-type stacked layers 5 includes the first P-type doped GaN layer 51 disposed proximate to the barrier layer 4 and the first P-type doped layer 52 disposed on the first P-type doped GaN layer 51, and the doping concentration of the first P-type doped GaN layer 51 is configured to decrease from the side proximate to the first P-type doped layer 52 to the side proximate to the substrate 1. The first P-type doped GaN layer 51 in the P-type stacked layers 5 can effectively block and reduce the diffusion of doping impurities in a P-type gate to the barrier layer 4 during the manufacturing process of the semiconductor device, thereby ultimately reducing the on-resistance of the device and improving the on-performance of the device, and improving the problem of decreased mobility in the non-gate region.

In some embodiments, the first P-type doped GaN layer 51 can be formed based on an intrinsic undoped gallium nitride (u-GaN) layer, and the first P-type doped layer 52 can be formed based on a heavily doped P-type layer. Though a high-temperature annealing process, doping impurities in the heavily doped P-type layer disposed on the intrinsic u-GaN layer are diffused into the intrinsic u-GaN layer, so that the intrinsic u-GaN layer is formed into the first P-type doped GaN layer 51, and the heavily doped P-type layer is formed into the first P-type doped layer 52. In an embodiment, process parameters of the high-temperature annealing process may be that an annealing temperature of 650 Celsius degrees (° C.) to 800° C. is used in a nitrogen atmosphere.

Corresponding to the first semiconductor device provided in the previous embodiment, the disclosure further provides a second semiconductor device, including a substrate, a buffer layer, a channel layer, a barrier layer, multiple prefabricated P-type stacked layers, a cap layer, a gate, a source, and a drain. The buffer layer is disposed on the substrate. The channel layer is disposed on the buffer layer. The barrier layer is disposed on the channel layer. The multiple prefabricated P-type stacked layers are disposed on the barrier layer along a direction from the substrate to the buffer layer. The cap layer is disposed on the multiple prefabricated P-type stacked layers. The gate is disposed on the cap layer. The source is disposed on the barrier layer. The drain is disposed on the barrier layer, and the drain and the source are disposed on two sides of the gate respectively.

Compared with the first semiconductor device provided above, the difference is that in the second semiconductor device, the multiple prefabricated P-type stacked layers are disposed above the barrier layer, and each prefabricated P-type stacked layer includes an intrinsic u-GaN layer and a heavily doped P-type layer disposed on the intrinsic u-GaN layer. The second semiconductor device is processed through a high-temperature annealing process, doping impurities in the heavily doped P-type layer can be diffused into the intrinsic u-GaN layer, thereby forming the first semiconductor device provided above. It should be noted that, corresponding to the two semiconductor devices mentioned above, when manufacturing the semiconductor device, the intrinsic u-GaN layer and the heavily doped P-type layer are manufactured on the barrier layer 4 in sequence. After the aforementioned high-temperature annealing process, the doping impurities in the heavily doped P-type layer are diffused into the intrinsic u-GaN layer, so that the intrinsic u-GaN layer is formed into the first P-type doped GaN layer 51, and the heavily doped P-type layer is formed into the first P-type doped layer 52.

In some embodiments, the first P-type doped layer 52 of the first semiconductor device may be a magnesium (Mg) doped P-type layer, which may be formed by a heavily Mg doped P-type layer. Exemplarily, the first P-type doped layer 52 may be a singly doped P-type aluminum gallium nitride (P-AlGaN) layer or P-GaN layer. In some embodiments, a doping concentration of Mg atoms in the first P-type doped layer 52 is greater than that of Mg atoms in the cap layer 6.

Exemplarily, the heavily doped P-type layer may be a P-AlGaN layer or a P-GaN layer with a single Mg atom doping concentration formed by using a Delta doped technology. Through the high-temperature annealing process, the Mg atoms doped in the heavily doped P-type layer are diffused into the intrinsic u-GaN layer, so that the intrinsic u-GaN layer is formed into the first P-type doped GaN layer 51, and the heavily doped P-type layer is formed into the first P-type doped layer 52, thereby effectively improving a concentration of holes of a gate region in the semiconductor device, and improving a threshold voltage of the semiconductor device having the aforementioned P-type stacked layers.

It should be noted that the above description uses the case where the doping impurities are Mg atoms as an example. In practical applications, the doping impurities may be atoms other than Mg atoms, and are not unique. That is, Mg atoms do not constitute the only limitation on the doping impurities in this disclosure.

In an embodiment, a maximum of the doping concentration of the first P-type doped GaN layer 51 of the first semiconductor device is smaller than the doping concentration of the first P-type doped layer 52 of the first semiconductor device, and the maximum of the doping concentration is related to the annealing time of the heat treatment process.

In some embodiments, the doping concentration of the first P-type doped layer 52 of the first semiconductor device is in a range of 5×10¹⁹ (5E+19) per cubic centimeters (cm⁻³) to 6E+19 cm⁻³.

In the embodiments of the disclosure, the doping concentration of the first P-type doped layer 52 of the first semiconductor device is greater than that of the first P-type doped GaN layer 51.

In some embodiments, the doping concentration of the first P-type doped layer 52 of the first semiconductor device is greater than that of the cap layer 6. In some embodiments, the doping concentration of the cap layer 6 is in a range of 3E+18 cm⁻³ to 4.5E+19 cm⁻³.

In practical applications, in order to ensure that the cap layer can completely deplete the 2DEG in the channel, a thickness of the barrier layer is often thinner. For example, in order to ensure that the cap layer 6 can completely deplete the 2DEG in the channel, the thickness of the barrier layer 4 can be set in a range of 15 nanometers (nm) to 30 nm. However, this will cause the Mg atoms that are not effectively doped in the P-GaN cap layer to easily form defects, and then permeate into the thinner barrier layer, increasing the internal electron scattering, resulting in a decrease in device mobility.

It should be noted that, since the first P-type doped GaN layer 51 is formed based on annealed intrinsic u-GaN layer, the doping of the first P-type doped GaN layer 51 is gradually permeated from the heavily doped P-type layer before annealing during the annealing process, and the permeation amount is relatively limited. In some embodiments, the doping concentration of the first P-type doped GaN layer 51 is smaller than that of the cap layer 6.

Based on this, the doping concentration of the first P-type doped GaN layer 51 is smaller than that of the cap layer 6, so that the problem of decreased mobility caused by permeation of defects into the thinner barrier layer of a lower layer due to ineffective doping in the central P-GaN cap layer of the related art, such as ineffective doped Mg.

Thus, the semiconductor device provided by some embodiments of the disclosure includes the multiple P-type stacked layers 5, each P-type stacked layer 5 includes the first P-type doped GaN layer 51 disposed on the barrier layer 4 and the first P-type doped layer 52 disposed on the first P-type doped GaN layer 51, and the doping concentration of the first P-type doped GaN layer 51 is configured to decrease from the side proximate to the first P-type doped layer 52 to the side proximate to the substrate 1. The P-type stacked layers 5 and the cap layer 6 form a P-type gate with an effective high hole concentration, thereby improving the threshold voltage of the device. Meanwhile, the first P-type doped GaN layer 51 in the P-type stacked layers 5 can effectively block and reduce the diffusion of doping impurities in the P-type gate to the barrier layer 4 during the manufacturing process of the semiconductor device, thereby ultimately reducing the on-resistance of the device and improving the on-performance of the device. In addition, the first P-type doped layer 52 uses the Delta doped technology, which can avoid the formation of high-density stacking faults during the heavy doping epitaxy process, resulting in poor crystal quality of P-GaN and poor gate voltage of the device. Therefore, the semiconductor device provided by the disclosure not only takes into account the requirement of increasing the threshold voltage of the gate region, but also improves the problem of decreased mobility in the non-gate region.

In some embodiments, exemplarily, a thickness of the cap layer 6 is smaller than or equal to 70 nm. A thickness of the first P-type doped layer 52 is in a range of 5 nm to 10 nm. A thickness of the first P-type doped GaN layer 51 is in a range of 3 nm to 6 nm.

In some embodiments, as shown in FIG. 1, a number of the P-type stacked layers 5 between the barrier layer 4 and the cap layer 6 may be one.

In other embodiments, as shown in FIG. 2, the number of the P-type stacked layers 5 between the barrier layer 4 and the cap layer 6 may be multiple, for example, four. When there are multiple P-type stacked layers 5 between the barrier layer 4 and the cap layer 6, the first P-type doped GaN layer 51 and the first P-type doped layer 52 can be alternatively arranged between the barrier layer 4 and the cap layer 6, presenting a periodic arrangement.

In some embodiments, in the multiple P-type stacked layers 5, a thickness of each of the first P-type doped GaN layer 51 and the first P-type doped layer 52 can be set in equal proportion. In other embodiments, in the multiple P-type stacked layers 5, the thickness of the first P-type doped GaN layer 51 in one of the multiple P-type stacked layers 5 which is closest to the substrate 1 is the thickest. In this way, by setting the thickness of the first P-type doped GaN layer 51 in one of the P-type stacked layers 5 which is closest to the substrate 1 to be relatively thickest, the permeation of ineffectively doped Mg atoms into the thinner barrier layer can be reduced, thereby avoiding the decrease in device mobility caused by increased internal electron scattering.

In the embodiments of the disclosure, the P-type stacked layers 5 and the cap layer 6 form the P-type gate, the source 7 and the drain 8 are disposed above the barrier layer 4 in pairs and isolated from each other, and are respectively disposed on two sides of the P-type gate, and the gate 10 is disposed on the P-type gate.

Based on the above gate structure, after the high-temperature annealing process described above, the P-type stacked layers 5 in the P-type gate undergoes diffusion of doping impurities. In the current P-GaN cap layer technology, it is difficult to achieve a high hole concentration using epitaxially grown P-GaN, which will result in a low threshold voltage of the semiconductor device. However, after the high-temperature annealing process, the hole concentration in the gate region of the semiconductor device having the aforementioned gate structure is effectively improved, thereby improving the threshold voltage of the semiconductor device. At the same time, the first P-type doped GaN layer 51 can effectively prevent the ineffectively doping impurities from permeating into the barrier layer 4, further taking into account the mobility of the non-gate region, thereby realizing a semiconductor device with low on-resistance and high threshold voltage.

The epitaxial structure of any one of the semiconductor devices described above is further described below.

In some embodiments, the barrier layer 4 may be an AlGaN barrier layer grown by a metal-organic chemical vapor deposition (MOCVD) process, and Al component in the AlGaN is 20% to 30% by mass.

In some embodiments, the channel layer 3 is a GaN channel layer further grown on the buffer layer 2 by using the MOCVD process, and has a thickness of 280 nm to 320 nm, and 300 nm can be selected in practical applications.

In some embodiments, the buffer layer 2 is a semi-insulating GaN high-resistance buffer layer formed by unintentional doping growth using the MOCVD process, and has a thickness of 4 microns (μm) to 5 μm, and a resistivity greater than 10⁸ ohms (Ω).

In some embodiments, a material of the substrate 1 may any one of silicon (Si), silicon carbon (SiC) and GaN, and a size of the substrate 1 may be in a range of 2 inch to 8 inch.

In some embodiments, the semiconductor device provided by any one of the above embodiments can further includes a passivation layer 9 disposed on the barrier layer 4.

The passivation layer 9 is located between the source 7 and the gate 10, and located between the drain 8 and the gate 10. It can be understood that the passivation layer 9 is filled into gaps between the source 7, the drain 8 and the P-type gate, to protect a surface of the epitaxial structure of the semiconductor device.

In some embodiments, the passivation layer 9 may be made from aluminum nitride (AlN) or silicon oxide (SiO₂).

The semiconductor device in the embodiment covers previously exposed surface of the barrier layer by the passivation layer disposed between the source and the gate, and between the drain and the gate, thereby protecting the surface of the epitaxial structure of the semiconductor device and improving the stability and reliability of the performance of the semiconductor device.

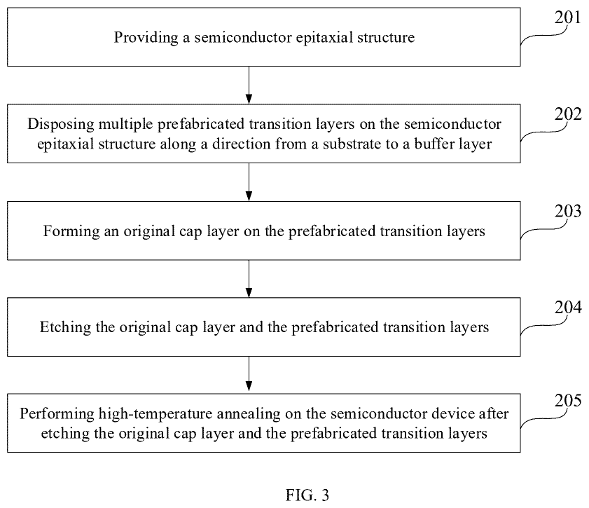

A manufacturing method of the semiconductor device shown in the above embodiments will be described below with reference to FIG. 3.

Please combining FIG. 1 and FIG. 6, and referring to FIG. 3, the manufacturing method of the semiconductor device provided by the embodiments of the disclosure includes the following steps 201-205.

In step 201, a semiconductor epitaxial structure is provided. Specifically, the semiconductor epitaxial structure includes a substrate 1, a buffer layer 2 disposed on the substrate 1, a channel layer 3 disposed on the buffer layer 2, and a barrier layer 4 disposed on the channel layer 3.

In step 202, multiple prefabricated P-type stacked layers 11 are disposed on the semiconductor epitaxial structure along a direction from the substrate 1 to the buffer layer 2. Specifically, each prefabricated P-type stacked layer 11 includes an intrinsic u-GaN layer 111 disposed proximate to the barrier layer 4 and a heavily doped P-type layer 112 disposed on the intrinsic u-GaN layer 111.

In some embodiments, the number of the prefabricated P-type stacked layers 11 is one, the above step 202 can include that the intrinsic u-GaN layer 111 is formed on the barrier layer 4, and the heavily doped P-type layer 112 is formed on the intrinsic u-GaN layer 111 by using a heavily Delta doped technology, to thereby form the prefabricated P-type stacked layer 11.

In other embodiments, the number of the prefabricated P-type stacked layers 11 is multiple, the above step 202 can further include that the intrinsic u-GaN layer 111 and the heavily doped P-type layer 112 are repeatedly prepared on the barrier layer 4, to form the multiple prefabricated P-type stacked layers 11.

Specifically, the intrinsic u-GaN layer 111 is made from a undoped GaN material, with a thickness of 3 nm to 6 nm, and a doping concentration of 0. The heavily doped P-type layer 112 is made from an AlGaN or GaN material, with a thickness of 5 nm to 10 nm, and a doping concentration of 5.5E+19 cm⁻³ to 8E+19 cm⁻³. It should be added that, taking Mg doping as an example, the heavily doped P-type layer 112 can be an AlGaN layer or a P-GaN layer with a single Mg doping concentration made by using the Delta doping technology.

In step 203, an original cap layer 61 is formed on the multiple prefabricated P-type stacked layers 11. Specifically, a doping concentration of the original cap layer 61 is smaller than that of the heavily doped P-type layer 112. Exemplarily, the doping concentration of the original cap layer 61 may be in a range of 3E+18 cm⁻³ to 5.5E+19 cm⁻³.

Exemplarily, a thickness of the original cap layer 61 prepared in the above step 203 is smaller than or equal to 70 nm.

In step 204, the original cap layer 61 and the multiple prefabricated P-type stacked layers 11 are etched.

Exemplarily, the above step 204 can include that the original cap layer 61 and the multiple prefabricated P-type stacked layers 11 are etched away except for the gate region by, for example, inductively coupled plasma (ICP), and etching is stopped at the surface of the barrier layer 4.

The multiple prefabricated P-type stacked layers 11 and the original cap layer 61 in a partial area above the barrier layer 4 can be etched away through the step 204, so that the multiple prefabricated P-type stacked layers 11 and the original cap layer 61 remain in a middle area of the barrier layer 4, and the remained prefabricated P-type stacked layers 11 and the remained original cap layer 61 form a part of the P-type gate. When the subsequent step 205 is performed at high-temperature annealing, the P-type gate can be subjected to high-temperature annealing treatment to diffuse the doping impurities in the heavily doped P-type layer 112 into the intrinsic u-GaN layer 111, so that the heavily doped P-type layer 112 is configured to be formed into the first P-type doped layer 52 as described in the above embodiments, and the intrinsic u-GaN layer 111 is configured to be formed into the first P-type doped GaN layer 51 as described in the above embodiments. It should be added that, due to the high-temperature annealing, the original cap layer 61 with the doping concentration of 3E+18 cm⁻³ to 5.5E+19 cm⁻³ is changed to the cap layer 6 as described above with a doping concentration of a range of 3E+18 cm⁻³ to 4.5E+19 cm⁻³. In this way, the doping concentration in the semiconductor layer above the intrinsic u-GaN layer 111 can be reduced by the intrinsic u-GaN layer 111 in the prefabricated P-type stacked layers 11, especially the doping impurities that are not effectively doped in the semiconductor layer above the intrinsic u-GaN layer 111 are diffused into the barrier layer 4, thereby improving the problem of decreased mobility in the non-gate region, thereby reducing the on-resistance of the device and improving the on-performance of the device.

Specific steps of etching are as follows.

A part area of the original cap layer 6 is photoetched to prepare a mask. The mask is formed by depositing silicon nitride (SiNₓ) and SiO₂. The prefabricated P-type stacked layers 11 and the original cap layer 61 in an area that is not covered by the mask are removed by using an etching process, and a gate region can be defined according to the remained prefabricated P-type stacked layers 11 and the remained original cap layer 61. The etching process can etch away the P-type stacked layers and the cap layer except for the gate region by ICP, and the etching stops on the surface of the barrier layer 4.

In step 205, the semiconductor device is subjected to the high-temperature annealing after etching the original cap layer 61 and the prefabricated P-type stacked layers 11. The doping impurities in the heavily doped P-type layer 111 are diffused into the intrinsic u-GaN layer 112 through the step 205, so that the prefabricated P-type stacked layers 11 is formed into the P-type stacked layers 5 described in the above embodiments.

Exemplarily, the above step 205 can include that the high-temperature annealing is performed after etching the original cap layer 61 and the prefabricated P-type stacked layers 11, so that the doping impurities in the heavily doped P-type layer 112 are diffused into the intrinsic u-GaN layer 111, and the heavily doped P-type layer 112 is formed into the first P-type doped layer 52. The high-temperature annealing is performed after etching the original cap layer 61 and the prefabricated P-type stacked layers 11, so that the doping impurities in the heavily doped P-type layer 112 are diffused into the intrinsic u-GaN layer 111, and the intrinsic u-GaN layer 111 is formed into the first P-type doped GaN layer 51.

Specifically, a forming process of the first P-type doped layer 52 is as follows.

The high-temperature annealing is performed after etching the original cap layer 61 and the prefabricated P-type stacked layers 11, so that the doping concentration of the heavily doped P-type layer 112 is reduced from a range of 5.5E+19 cm⁻³ to 8E+19 cm⁻³ to a range of 5E+19 cm⁻³ to 6E+19 cm⁻³, to form the first P-type doped layer 52.

Specifically, a forming process of the first P-type doped GaN layer 51 is as follows.

The high-temperature annealing is performed after etching the original cap layer 61 and the prefabricated P-type stacked layers 11, so that the doping concentration of the intrinsic u-GaN layer 111 is increased, to form the first P-type doped GaN layer 51.

In some embodiments, the high-temperature annealing in the step 203 refers to performing an annealing process in a nitrogen atmosphere at an annealing temperature of 650° C. to 800° C.

After high-temperature annealing, the doping concentration of the intrinsic u-GaN layer 111 is increased, to form the first P-type doped GaN layer 51. The doping concentration of the first P-type doped GaN layer 51 decreases gradually from top to bottom, and the maximum doping concentration of the first P-type doped GaN layer 51 is related to the annealing time.

The manufacturing method of the semiconductor device provided by the embodiment can manufacture a semiconductor device with the P-type stacked layers. Combined with the high-temperature annealing process, the doping impurities in the heavily doped P-type layer in the prefabricated P-type stacked layers are further diffused into the intrinsic u-GaN layer to form the P-type stacked layers. The intrinsic u-GaN layer (formed into the first P-type doped GaN layer after the high-temperature annealing) is used to effectively block the doping impurities in the cap layer from diffusing into the barrier layer during the epitaxial preparation process, thereby ensuring the mobility of the device. In addition, the method can be simply implemented through epitaxial preparation and etching processes, and the method has high repeatability and controllability, and is suitable for large-scale production of semiconductor devices.

In an embodiment, in the semiconductor device manufactured by the manufacturing of the semiconductor device provided by the embodiment, the P-type stacked layers can effectively increase the hole concentration in the gate region of the semiconductor device, thereby increasing the threshold voltage of the device. Meanwhile, the intrinsic u-GaN layer (formed into the first P-type doped GaN layer after the high-temperature annealing) is used to effectively block the diffusion of the doping impurities in the cap layer into the barrier layer during the epitaxial preparation process, thereby ensuring the mobility of the device. In other words, the manufacturing method of the semiconductor device provided by the embodiments can obtain a semiconductor device that takes both threshold voltage and mobility into consideration.

In some embodiments, before the high-temperature annealing is performed on the semiconductor device, the manufacturing method of the semiconductor device may further include the following steps.

A passivation layer is prepared on an exposed surface of the barrier layer, for example, the passivation layer is evaporated on the exposed surface of the barrier layer.

The passivation layer is etched to expose the gate region, the source region and the drain region, to thereby respectively prepared the gate, the source and the drain.

In the manufacturing method of the semiconductor device disclosed in the embodiment, after forming the P-type gate and before forming the gate, the passivation layer is evaporated on the exposed surfaces of the barrier layer and the P-type gate, and the material of the passivation layer can be AlN or SiO₂. After forming the passivation layer, the passivation layer in a part area above the barrier layer and the passivation layer on the upper surface of the P-type gate need to be removed, and the position where the passivation layer is removed is used to prepare the gate, the source and the drain. Specifically, the upper surface of the P-type gate is used to prepare the gate, and the area on the barrier layer where the passivation layer is removed is used to prepare the source and the drain.

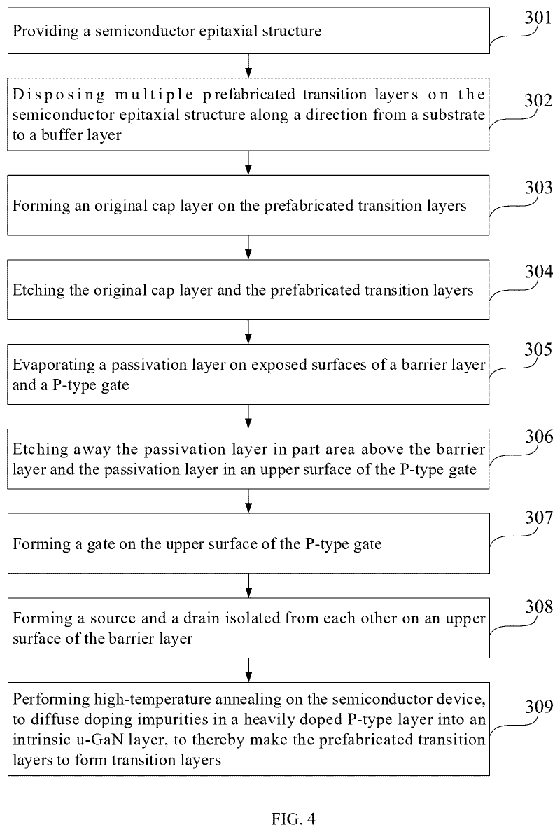

In an embodiment, FIG. 4 illustrates another flowchart of the manufacturing method of the semiconductor device according to some embodiments of the disclosure. Referring to FIG. 4, an embodiment of the disclosure provides a manufacturing method of a semiconductor device, which prepares a passivation layer to protect a surface of an epitaxial structure of the semiconductor device, and the manufacturing method can include the following steps 301-309.

In step 301, a semiconductor epitaxial structure is provided.

In step 302, multiple prefabricated P-type stacked layers are disposed on the semiconductor epitaxial structure along a direction from the substrate to the buffer layer.

In step 303, an original cap layer is formed on the multiple prefabricated P-type stacked layers.

In step 304, the original cap layer and the multiple prefabricated P-type stacked layers are etched.

In step 305, a passivation layer is evaporated on exposed surfaces of the barrier layer and the P-type gate.

In step 306, the passivation layer in a partial area above the barrier layer and on the upper surface of the P-type gate is etched away.

In step 307, a gate is formed on the upper surface of the P-type gate.

In step 308, the source and the drain isolated from each other are formed on an upper surface of the barrier layer.

In step 309, the semiconductor device is subjected to high-temperature annealing, so that the doping impurities in the heavily doped P-type layer are diffused into the intrinsic u-GaN layer, to make the prefabricated P-type stacked layers to form the P-type stacked layers.

It should be noted that the disclosure does not have strict requirements on the preparation order of the gate, the source and the drain. In actual applications, the gate, the source and the drain can be formed based on any preparation order, and no sole limitation is made here.

The specific operation method of each step can be found in the manufacturing method of the semiconductor device described above, and will not be elaborated here.

The manufacturing method of the semiconductor device provided in the embodiment forms a protective dielectric film on the surface of the semiconductor device by evaporating the passivation layer on the exposed surfaces of the barrier layer and the P-type gate, thereby improving the influence of the surface effect on the working stability of the device and improving the reliability of the semiconductor device.

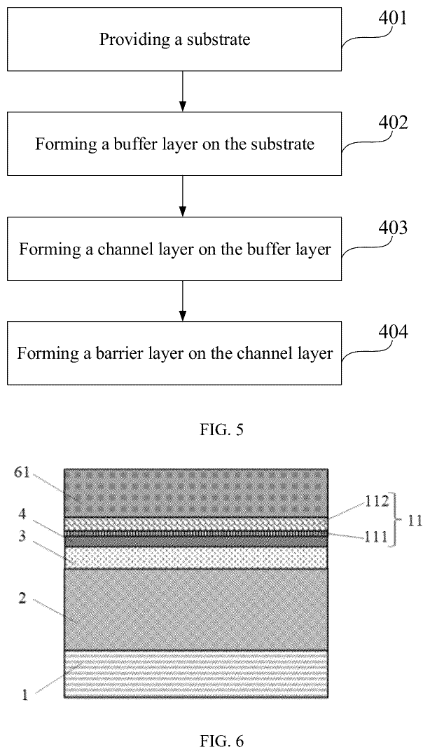

FIG. 5 illustrates a flowchart of a manufacturing method of a semiconductor epitaxial structure according to some embodiments of the disclosure.

Referring to FIG. 5, in some embodiments of the disclosure, the manufacturing method of the semiconductor epitaxial structure in the step 201 or the step 301 can include the follows steps 401-404.

In step 401, a substrate is provided.

In the above step 401, a material of the substrate can be any one of Si, SiC and GaN, and a size of the substrate can be in a range of 2 inch to 8 inch.

In step 402, a buffer layer is formed on the substrate.

Exemplarily, the above step 402 can include that an unintentionally doped semi-insulating GaN high-resistance buffer layer is epitaxially grown on the substrate by using the MOCVD process. In an embodiment, a resistivity of the GaN high-resistance buffer layer is greater than 10 ohms.

A thickness of the buffer layer prepared in the above step 402 can be in a range of 4 μm and 5 μm.

In step 403, a channel layer is formed on the buffer layer.

Exemplarily, the above step 403 can include that a GaN channel layer is further grown on the GaN high-resistance buffer layer by using the MOCVD process.

A thickness of the channel layer prepared in the above step 403 can be in a range of 280 nm to 320 nm.

In step 404, a barrier layer is formed on the channel layer.

Exemplarily, the above step 403 can include that an AlGaN barrier layer is grown on the GaN channel layer by using the MOCVD process. A mass percentage of Al component in the AlGaN used to prepare the AlGaN barrier layer may be between 20% and 30%.

A thickness of the barrier layer prepared in the above step 404 can be in a range of 15 nm to 30 nm.

By using the above preparing method of the semiconductor epitaxial structure, the epitaxial structure of the semiconductor device as shown in FIG. 6 can be obtained.

As shown in FIG. 6, the epitaxial structure of the semiconductor device can include a substrate 1, a buffer layer 2, a channel layer 3, and a barrier layer 4. The buffer layer 2 is disposed on the substrate 1. The channel layer 3 is disposed on the buffer layer 2. The barrier layer 4 is disposed on the channel layer 3.

In some embodiments, the epitaxial structure of the semiconductor device can further include prefabricated P-type stacked layers 11 disposed on the barrier layer 4. Each prefabricated P-type stacked layer 11 includes an intrinsic u-GaN layer 111 and a heavily doped P-type layer 112 disposed on the intrinsic u-GaN layer 111. Corresponding to the epitaxial structure of the semiconductor device, the manufacturing method of the semiconductor epitaxial structure may further include that the intrinsic u-GaN layer is formed on the barrier layer, and the heavily doped P-type layer is formed on the intrinsic u-GaN layer using a heavy Delta doping technology.

In some embodiments, the epitaxial structure of the semiconductor device can further include an original cap layer 61 disposed on the heavily doped P-type layer 112. Corresponding to the epitaxial structure of the semiconductor device, the manufacturing method of the semiconductor epitaxial structure may further include that the original cap layer 61 is formed on the heavily doped P-type layer 112.

It should be noted that the division of the epitaxial structure of the semiconductor device in each embodiment of the disclosure is only an example and does not constitute the sole limitation of the disclosure. In other words, the epitaxial structure of the semiconductor device in the disclosure may include but is not limited to: the substrate 1, the buffer layer 2, the channel layer 3 and the barrier layer 4. Furthermore, the epitaxial structure of the semiconductor device in the disclosure may also include: the prefabricated P-type stacked layers 11 and the original cap layer 61.

In some embodiments of the disclosure, after the epitaxial structure of the semiconductor device is prepared, the epitaxial structure of the semiconductor device may be subjected to the high-temperature annealing process, so that the prefabricated P-type stacked layers 11 are formed as the P-type stacked layers 5. That is, in some embodiments, as shown in FIG. 6, the epitaxial structure of the semiconductor device in the disclosure may include: a substrate 1, a buffer layer 2, a channel layer 3, a barrier layer 4, prefabricated P-type stacked layers 11, and an original cap layer 6.

The flowcharts and block diagrams in the drawings illustrate the architecture, functionality, and operation of possible implementations of systems and methods according to various embodiments of the disclosure. In this regard, each block in the flowcharts or block diagrams may represent a module, a segment, or a portion of code, which includes one or more executable instructions for implementing specified logical functions. It should also be noted that, in some alternative implementations, the functions indicated in the blocks may occur in an order different from that depicted in the drawings. For example, two consecutive blocks may in fact be executed substantially concurrently, or they may sometimes be executed in reverse order, depending on the functionality involved. It should also be noted that each block in the block diagrams and/or flowcharts, as well as combinations of blocks therein, may be implemented by dedicated hardware-based systems that perform specified functions or operations, or by a combination of dedicated hardware and computer instructions.

Although several embodiments of the disclosure have been shown and described herein, it will be obvious to those skilled in the art that such embodiments are provided by way of example only. Numerous variations, modifications, and alternative implementations may occur to those skilled in the art without departing from the spirit and scope of the disclosure. It should be understood that various alternative embodiments of the disclosure described herein may be employed in practicing the disclosure. The appended claims are intended to define the scope of the disclosure and thus cover equivalents or alternatives falling within the scope of these claims.

What is claimed is:

1. A semiconductor device, comprising:
a substrate;
a buffer layer, disposed on the substrate;
a channel layer, disposed on the buffer layer;
a barrier layer, disposed on the channel layer;
a cap layer, disposed on the barrier layer;
a gate, disposed on the cap layer;
a source, disposed on the barrier layer; and
a drain, disposed on the barrier layer, wherein the drain and the source are disposed on two sides of the gate respectively;
wherein the semiconductor device further comprises: a plurality of P-type stacked layers, and the plurality of P-type stacked layers are disposed between the barrier layer and the cap layer along a direction from the substrate to the buffer layer; and each of the plurality of P-type stacked layers comprises a first P-type doped gallium nitride (GaN) layer disposed proximate to the barrier layer and a first P-type doped layer disposed on the first P-type doped GaN layer; and
wherein a doping concentration of the first P-type doped GaN layer is configured to decrease from a side proximate to the first P-type doped layer to a side proximate to the substrate.

2. The semiconductor device as claimed in claim 1, wherein a doping concentration of the first P-type doped layer is greater than the doping concentration of the first P-type doped GaN layer.

3. The semiconductor device as claimed in claim 1, wherein a doping concentration of the first P-type doped layer is greater than a doping concentration of the cap layer.

4. The semiconductor device as claimed in claim 1, wherein the doping concentration of the first P-type doped GaN layer is smaller than a doping concentration of the cap layer.

5. The semiconductor device as claimed in claim 1, wherein a doping concentration of the first P-type doped layer of the first semiconductor device is in a range of 5×10¹⁹ cm⁻³ to 6×10¹⁹ cm⁻³.

6. The semiconductor device as claimed in claim 1, wherein a doping concentration of the cap layer is in a range of 3×10¹⁸ cm⁻³ to 4.5×10¹⁹ cm⁻³.

7. The semiconductor device as claimed in claim 1, wherein a thickness of the first P-type doped layer is greater than a thickness of the first P-type doped GaN layer, and a thickness direction is the direction from the substrate to the buffer layer.

8. The semiconductor device as claimed in claim 7, wherein the thickness of the first P-type doped GaN layer is in a range of 3 nm to 6 nm.

9. The semiconductor device as claimed in claim 7, wherein the thickness of the first P-type doped layer is in a range of 5 nm to 10 nm.

10. The semiconductor device as claimed in claim 1, wherein the first P-type doped GaN layer is a magnesium (Mg) doped GaN layer; and the first P-type doped layer is a Mg doped P-type layer.

11. The semiconductor device as claimed in claim 1, wherein the first P-type doped GaN layer is a singly doped P-type aluminum gallium nitride (P-AlGaN) layer.

12. The semiconductor device as claimed in claim 1, wherein the first P-type doped GaN layer is a singly doped P-type gallium nitride (P-GaN) layer.

13. The semiconductor device as claimed in claim 1, further comprising:
a passivation layer, disposed on the barrier layer, wherein the passivation layer is located between the source and the gate, and is located between the drain and the gate.

14. The semiconductor device as claimed in claim 1, wherein in the plurality of P-type stacked layers, a thickness of the first P-type doped GaN layer in one of the plurality of P-type stacked layers closest to the substrate is the thickest.

15. A manufacturing method of a semiconductor device, comprising:
providing a semiconductor epitaxial structure, wherein the semiconductor epitaxial structure comprises: a substrate, a buffer layer disposed on the substrate, a channel layer disposed on the buffer layer, and a barrier layer disposed on the channel layer;
disposing a plurality of prefabricated P-type stacked layers on the semiconductor epitaxial structure along a direction from the substrate to the buffer layer, wherein each of the plurality of prefabricated P-type stacked layer comprises an intrinsic undoped gallium nitride (u-GaN) layer disposed proximate to the barrier layer, and a heavily doped P-type layer disposed on the intrinsic u-GaN layer;
forming an original cap layer on the plurality of prefabricated P-type stacked layers; and
etching the original cap layer and the plurality of prefabricated P-type stacked layers, and annealing the semiconductor device after etching the original cap layer and the plurality of prefabricated P-type stacked layers, so that the prefabricated P-type stacked layers is formed into the P-type stacked layers.

16. The manufacturing method as claimed in claim 15, wherein the annealing the semiconductor device after etching the original cap layer and the plurality of prefabricated P-type stacked layers, so that the prefabricated P-type stacked layers is formed into the P-type stacked layers comprises:
annealing the semiconductor device after etching the original cap layer and the plurality of prefabricated P-type stacked layers, so that the heavily doped P-type layer is formed into the first P-type doped layer, comprising:
annealing the semiconductor device after etching the original cap layer and the plurality of prefabricated P-type stacked layers, to reduce a doping concentration of the heavily doped P-type layer from a range of 5.5×10¹⁹ cm⁻³ to 8×10¹⁹ cm⁻³to a range of 5×10¹⁹ cm⁻³ to 6×10¹⁹ cm⁻³, thereby forming the first P-type doped layer;
annealing the semiconductor device after etching the original cap layer and the plurality of prefabricated P-type stacked layers, so that the intrinsic u-GaN layer is formed into the first P-type doped GaN layer, comprising:
annealing the semiconductor device after etching the original cap layer and the plurality of prefabricated P-type stacked layers, to increase a doping concentration of the intrinsic u-GaN layer, thereby forming the first P-type doped GaN layer.

17. The manufacturing method as claimed in claim 15, wherein the disposing a plurality of prefabricated P-type stacked layers on the semiconductor epitaxial structure comprises: disposing the heavily doped P-type layer on the intrinsic u-GaN layer, comprising:
forming the heavily doped P-type layer on the intrinsic u-GaN layer using a heavy Delta doping technique.

18. The manufacturing method as claimed in claim 15, wherein the disposing a plurality of prefabricated P-type stacked layers on the semiconductor epitaxial structure comprises: disposing the heavily doped P-type layer on the intrinsic u-GaN layer, comprising:
forming an Mg doped P-type layer on the intrinsic u-GaN layer.

19. The manufacturing method as claimed in claim 15, wherein the etching of the original cap layer and the plurality of prefabricated P-type stacked layers comprises:
removing the original cap layer and the plurality of prefabricated P-type stacked layers except in a gate region by etching, with the etching stopping at a surface of the barrier layer.

20. The manufacturing method as claimed in claim 15, wherein before the annealing the semiconductor device, the manufacturing method further comprises:
forming a passivation layer on an exposed surface of the barrier layer; and
etching the passivation layer to expose a gate region, a source region and a drain region to form a gate, a source and a drain respectively.
